(19) United States
(12) Patent Application Publication
(10) Pub. No.: US 2008/0079500 A1
(43) Pub. Date: Apr. 3, 2008

(54) Method And System For A Local Oscillator (LO) Generator Architecture For Multi-Band Wireless Systems

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 11/536,123

(22) Filed: Sep. 28, 2006

(51) Int. Cl. H03L 7/00

(52) U.S. Cl. 331/16

(57) ABSTRACT

Aspects of a method and system for identifying a local oscillator (LO) generator architecture for multi-band wireless systems are presented. Aspects of the system may include a VCO control processor and/or fractional N synthesizer control processor that enables selection, from a plurality of frequencies, of a frequency of oscillation of a signal generated by a single VCO by enabling configuration of one or more capacitor and/or varactor circuits in a multi-standard wireless communication system that processes a plurality of RF signals located in different frequency bands using the single VCO. In response to the selection, at least one circuit may enable generation, utilizing the single VCO, of a local oscillator signal having a frequency within a plurality of frequency ranges comprising 850 MHz to 1 GHz, 1.7 GHz to 2.1 GHz, 2.4 GHz to 2.5 GHz, and 4.9 GHz to 5.9 GHz.

### CROSS-REFERENCE TO RELATED APPLICATIONS/INCORPORATION BY REFERENCE

NOT APPLICABLE.

### FIELD OF THE INVENTION

Certain embodiments of the invention relate to wireless communication. More specifically, certain embodiments of the invention relate to a method and system for a local oscillator (LO) generator architecture for multi-band wireless systems.

### BACKGROUND OF THE INVENTION

As mobile terminals support a wider range of content from voice to data to video, they may be required to receive a correspondingly wider range of frequencies. For example, Bluetooth signals may be transmitted having frequencies in the 2.4 GHz frequency band; wireless local area network (WLAN) signals may be transmitted having frequencies in the 2.4 GHz frequency band, or 5 GHz frequency band. Signals transmitted in Global System for Mobile Communications (GSM) networks may have frequencies in the 900 MHz frequency band, signals transmitted in Digital Cellular System (DCS) networks may have frequencies in the 1.8 GHz frequency band, and signals transmitted in Personal Communications System (PCS) networks may have frequencies in the 1.9 GHz frequency band, for example.

Enabling a mobile terminal to receive signals from the various frequency bands may require the implementation of mobile terminals that utilize a plurality of local oscillator circuits. For example, one local oscillator circuit may be utilized for reception of GSM signals, another for reception of PCS signals, and yet another for reception of Bluetooth signals. The use of multiple local oscillator circuits may increase the cost of mobile terminals in addition to requiring increased power consumption and circuit board space utilization.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A method and system for a local oscillator (LO) generator architecture for multi-band wireless systems, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1A is a block diagram of an exemplary multi-standard wireless communication system, in accordance with an embodiment of the invention.

FIG. 1B is a block diagram of an exemplary local oscillator (LO) generator architecture for multi-band signals, in accordance with an embodiment of the invention.

FIG. 2 is a diagram illustrating circuitry for a tunable VCO with switched capacitors, in accordance with an embodiment of the invention.

FIG. 3 is a diagram illustrating exemplary circuitry for a tunable VCO with switched varactors, in accordance with an embodiment of the invention.

FIG. 4 is a flow chart illustrating exemplary steps for selecting a VCO frequency, in accordance with an embodiment of the invention.

FIG. 5 is a flow chart illustrating exemplary steps for generating a LO frequency within a selected frequency band, in accordance with an embodiment of the invention.

### DETAILED DESCRIPTION OF THE INVENTION

Certain embodiments of the invention may be found in a method and system for a local oscillator (LO) generator architecture for multi-band wireless systems. In various embodiments of the invention, a single voltage control oscillator (VCO) circuit may generate VCO signals having frequencies within a frequency range. In an exemplary embodiment of the invention, the frequency range may span from approximately 3 GHz to approximately 4.5 GHz. The frequency of a generated VCO signal may be tunable through coarse tuning adjustments by configuring capacitors in the VCO circuit. The frequency of a generated VCO signal may be tunable through fine-tuning adjustments by generating a control voltage input signal, V_{cntl}, for varactor circuits within the VCO circuit. Local oscillator signals for frequency bands utilized in various wireless communication networks may be generated by frequency dividing the generated VCO signal, and/or by frequency mixing the VCO signal with a frequency divided version of the VCO signal. Local oscillator signals may also be generated by frequency dividing the signal generated through the frequency mixing.

Various embodiments of the invention may be utilized to generate timing or clock signals for Bluetooth, Zigbee, digital video broadcast handheld (DVB-H), WLAN, wideband code division multiple access (WCDMA), high speed downlink packet access (HSDPA), high speed uplink packet access (HSUPA), GSM, general packet radio service (GPRS), enhanced data for GSM evolution (EDGE), and global positioning system (GPS) networks.

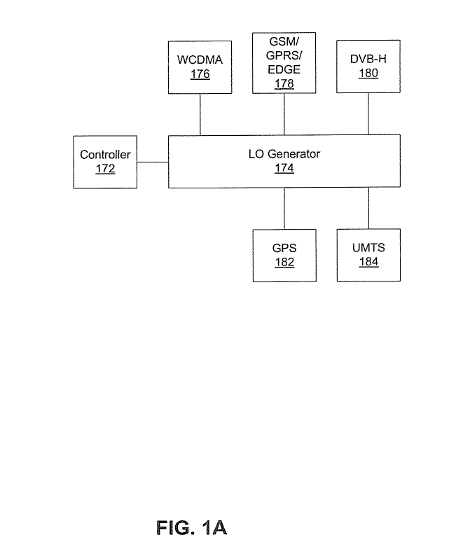

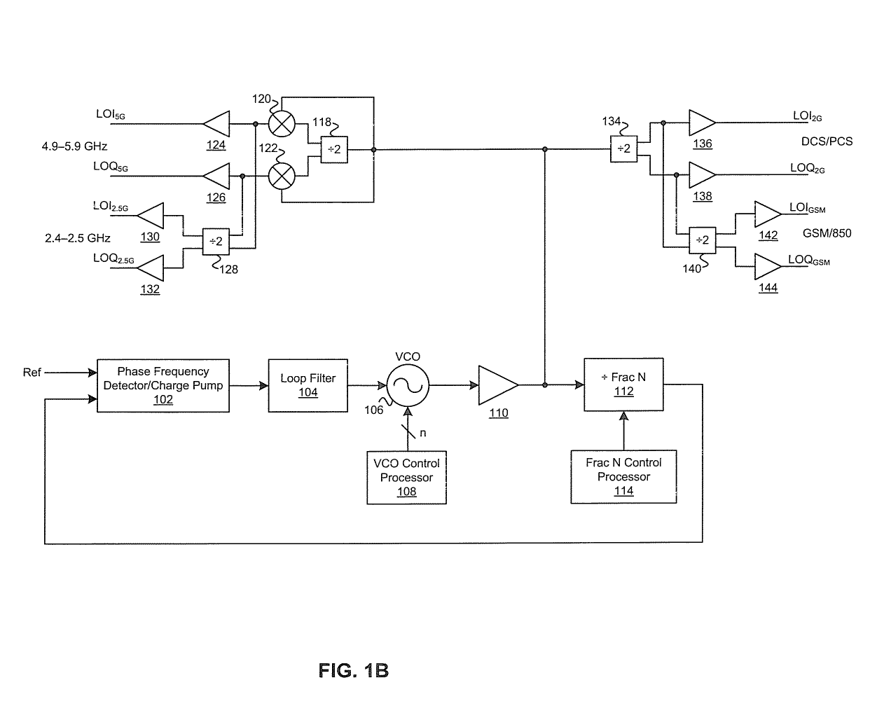

FIG. 1A is a block diagram of an exemplary multi-standard wireless communication system, in accordance with an embodiment of the invention. Referring to FIG. 1A, there is shown a controller 172, a local oscillator (LO) generator 174, a WCDMA block 716, a GSM/GPRS/EDGE block 178, a DVB-H block 180, a GPS block 182, and a universal mobile telecommunication system (UMTS) block 184.

The controller 172 may comprise suitable logic, circuitry, and/or code that may enable the LO generator 174 to generate timing signals for multiple wireless communication standards. The LO generator 174 may comprise suitable logic, circuitry, and/or code that may enable generation of signals having a specified frequency range such that the generated signal may be utilized for generating local oscillators signals within frequency ranges as specified for a plurality of wireless communication standards.

The WCDMA block 176 may comprise suitable logic, circuitry, and/or code that may enable generation of signals having a frequency range as specified for WCDMA. The GSM/GPRS/EDGE block 178 may comprise suitable logic, circuitry, and/or code that may enable generation of signals having a frequency range as specified for GSM, GPRS, and/or EDGE. The DVB-H block 180 may comprise suitable logic, circuitry, and/or code that may enable generation of signals having a frequency range as specified for DVB-H. The GPS block 182 may comprise suitable logic, circuitry, and/or code that may enable generation of signals having a frequency range as specified for GPS. The UMTS block 184 may comprise suitable logic, circuitry, and/or code that may enable generation of signals having a frequency range as specified for UMTS. FIG. 1B is a block diagram of an exemplary local oscillator (LO) generator architecture for multi-band signals, in accordance with an embodiment of the invention. Referring to FIG. 1B, there is shown a phase frequency detector and charge pump (PFD/CP) 102, a loop filter 104, a VCO 106, a VCO control processor 108, a plurality of signal buffers 110, 124, 126, 130, 132, 136, 138, 142, and 144, a fractional N (Frac N) synthesizer block 112, and a Frac N control processor 114. Also shown in FIG. 1B, a plurality of frequency divider blocks 118, 128,134, and 140, and a plurality of frequency mixer blocks 120 and 122.

The PFD/CP block 102 may comprise suitable circuitry, logic, and/or code that may enable generation of a current, i(s), based on a reference input signal, Ref, and a feedback signal. The variable, s, may be a variable representing a frequency of the signal i(s). The Ref signal may be generated by an oscillator crystal. The Ref signal may be defined by a frequency, S_{Ref}, amplitude, A_{Ref}, and/or phase, φ_{Ref}. The PFD function within the PFD/CP block 102 may enable detection of phase differences between the Ref signal and the feedback signal at various time instants. The CP function within the PFD/CP block 102 may enable generation of the current i(s) based on the detected phase differences.

The loop filter 104 may comprise suitable circuitry, logic, and/or code that may be utilized to enable generation of a control voltage signal, V_{Cntl}, based on a received current i(s). The loop filter 104 may be characterized by an impedance that varies as a function of frequency, Zₗₒₒₚ(s), where the variable s may represent the frequency of the signal i(s). An approximate value for the control voltage V_{Cntl} may be represented as shown in the following equation:

V_{Cntl}(s)≅Zₗₒₒₚ(s)·i(s) Equation [1]

The VCO 106 may comprise suitable circuitry, logic, and/or code that may enable generation of a VCO signal based on an input control voltage V_{Cntl}, and an input control word. The input control word may comprise a binary word containing n bits, where n is a variable representing the number of bits in the binary word. The VCO signal generated by the VCO 106 may be defined by an amplitude, a phase, and/or a frequency. The frequency of the VCO signal may be within a specified frequency range. In an exemplary embodiment of the invention, the frequency range may comprise frequencies from approximately 3 GHz to approximately 4.5 GHz.

In various embodiments of the invention, a VCO frequency may be selected within a given frequency range based on a fine-tuning adjustment process, and/or by a coarse tuning adjustment process. A fine-tuning adjustment may be performed by modifying the input control voltage, V_{Cntl}, supplied to the VCO 106. The generated signal may have a VCO frequency, s_{VCO}, which may be represented as shown in the following equation:

s_{VCO}≅K_{VCO}·V_{cntl} Equation [2]

where K_{VCO} may represent a VCO gain factor that may relate an amplitude of the input control voltage, V_{Cntl}, to a corresponding frequency of the generated output signal from the VCO 106. The value of the VCO gain factor, K_{VCO}, may be a function of capacitance of circuitry within the VCO 106.

A coarse tuning adjustment may be performed by modifying a capacitance of circuitry within the VCO 106 to modify the VCO gain factor. In this regard, the VCO gain factor, K_{VCO}, may be a function of the VCO capacitance, C_{VCO}. An exemplary relationship between the VCO gain factor and the VCO capacitance, may be represented as shown in the following equation:

$$\frac{\partial {K}_{VCO}}{\partial {C}_{VCO}} < 0 \qquad Equation [ 3 ]$$

In this regard, the VCO gain factor may decrease for increasing values of VCO capacitance. Alternatively, the VCO gain factor may increase for decreasing value of VCO capacitance. Thus, with reference to equation [2], for a given control voltage level, V_{Cntl}, an increase in C_{VCO} may result in a decrease in the VCO frequency, s_{VCO}, generated by the VCO 106.

The VCO control processor 108 may comprise suitable logic, circuitry, and/or code that may enable generation of a control word. In an exemplary embodiment of the invention, the control word may comprise a plurality of n binary bits, where n is a variable, which may indicate the number of bits in the control word. The VCO control processor 108 may generate the control word in response to code that enables selection of a VCO signal frequency based on a coarse turning adjustment procedure.

The signal buffer 110 may comprise suitable logic, circuitry, and/or code that may enable reception of an input signal, and generation of an output signal having an amplitude, phase, and frequency that is substantially similar to the corresponding quantities in the input signal. The signal buffers 124, 126, 130,132,136, 138,142, and 144 may be substantially similar to the signal buffer 110.

The Frac N synthesizer block 112 may comprise suitable logic, circuitry, and/or code that may enable reception of an input signal and an input division number N control word, and generation of a feedback signal. The feedback signal may be defined by an amplitude, A_{FB}, a phase, φ_{FB}, and/or a frequency, s_{FB}. For an input signal having a frequency, s_{VCO}, and for a input division number N, the Frac N synthesizer block 112 may generate a feedback signal having a frequency, s_{FB}, which may be represented as shown in the following equation:

$${s}_{FB} ≅ \frac{{s}_{VCO}}{N} \qquad Equation [ 4 ]$$

The Frac N control processor 114 may comprise suitable logic, circuitry, and/or code that may enable generation of a control word. In an exemplary embodiment of the invention, the control word may comprise a representation of a division number N, where N is a variable, which may indicate a frequency division scale factor. The Frac N control processor 114 may generate the control word in response to code that may enable selection of a frequency division scale factor to be utilized for generation of a feedback signal. The selection of the division number N may determine a frequency range for generated VCO signals. In an exemplary embodiment of the invention, the frequency range for generated VCO signals may comprise a frequency range from approximately 3 GHz, to about 4.5 GHz.

The frequency divider block 118 may comprise suitable logic, circuitry, and/or code that may enable reception of an input signal having a frequency sᵢ, and generation of an output signal having a frequency sₒ, the value of which may be represented as shown in the following equation:

$${s}_{O} ≅ \frac{{s}_{i}}{d} \qquad Equation [ 5 ]$$

where d is a variable, which may represent the frequency division scale factor utilized by the frequency divider block 118. In an exemplary embodiment of the invention, d=2. The frequency divider block 118 may generate output signals that comprise an in-phase (I) component, and a quadrature phase (Q) component. The I signal may be defined by a frequency, sₒ, amplitude, Aₒ(l), and/or phase φₒ(I). The Q signal may be defined by a frequency, sₒ, amplitude, Aₒ(Q), and/or phase φₒ(Q). Together, the I and Q signals may comprise a complex variable representation of the output signal. The frequency divider blocks 128, 134, and 140 may be substantially similar to the frequency divider block 118.

The frequency divider block 120 may comprise suitable logic, circuitry, and/or code that may enable reception of input signals, i₁ and i₂, having respective frequencies of sᵢ₁ and sᵢ₂, and generation of an output signal having a frequency sₒ. In an exemplary embodiment of the invention, a value of the output signal frequency, sₒ, may be represented as shown in the following equation:

sₒ≅sᵢ₁+sᵢ₂ Equation [6]

### The frequency divider block 122 may be substantially similar to the frequency divider block 120.

In operation, the VCO control processor 108 may generate an n-bit binary control word that is utilized to configure the VCO 106. The n-bit binary control word may be utilized by the VCO 106 to determine a VCO gain factor, K_{VCO} . The Frac N control processor 114 may generate an input division number N. The division number N may be utilized by the Frac N synthesizer block 112 to scale a VCO frequency of an input signal generated by the VCO 106. The division number N may establish a frequency range for signals generated by the VCO 106.

The PFD/CP block 102 may receive an input reference signal, generated by a crystal oscillator, and a feedback signal, generated by the Frac N synthesizer block 112. At a given time instant t₀, the PFD/CP block 102 may compare the signal level of the input reference signal, A_{Ref}(t₀) and the signal level of the feedback signal A_{FB}(t₀). At the given time instant, the signal level, A_{Ref}(t₀), may be based on the frequency, S_{Ref}, and phase, φ_{Ref}, of the input reference signal. Similarly, the signal level, A_{FB}(t₀), may be based on the frequency, s_{FB}, and phase, φ_{FB}, of the feedback signal. Based on the comparison between the signal levels, A_{Ref}(t₀) and A_{FB}(t₀), a phase and/or frequency difference between the input reference signal and the feedback signal may be detected. Based on the detected phase and/or frequency differences the PFD/CP block 102 may generate a corresponding current level i(tₒ). Based on the current level generated at the current time instant, and at one or more preceding time instants, the PFD/CP block 102 may generate a current i(s), where the variable, s, may represent a frequency of the current signal.

The loop filter 104 may receive the current i(s) at a time instant t₀′, where t₀′ may represent a time instant t₀+δ, and generate a control voltage V_{cntl}(t₀′). The VCO block 106 may receive the control voltage, V_{cntl}(t₀′), at a time instant t₀″, where t₀″ may represent a time instant t₀′+δ. Based on the received control voltage, and the configured n-bit binary control word received from the VCO control processor 108, the VCO block 106 may generate a VCO signal having a frequency s_{VCO}(t₀″).

The Frac N synthesizer block 112 may receive the VCO signal at a time instant t₀′″, where t₀′″ may represent a time instant t₀″+δ. Based on the received VCO signal, and the previously configured division number N from the Frac N control processor 114, the Frac N synthesizer block 112 may generate a feedback signal having a frequency s_{FB}(t₀′″), which may be represented as shown in the following equation:

$${s}_{FB} ( {t}^{′′′} ) ≅ \frac{{s}_{VCO} ( {t}^{″} )}{N} \qquad Equation [ 7 ]$$

The feedback signal generated by the Frac N synthesizer block 112 at a time instant t₀″″, where t₀″″ may represent a time instant t₀′″+δ, may be utilized to generate subsequent VCO signal.

In various embodiments of the invention, a plurality of LO signals may be generated based on a current VCO signal. For example, when generating an LO signal having a frequency in the 5 GHz frequency band, the VCO block 106 may generate a current VCO signal having a frequency of approximately 3.5 GHz. The 3.5 GHz VCO signal may be frequency divided by the frequency divider block 118 to generate corresponding I and Q signals, each having a frequency of about 1.75 GHz. In an exemplary embodiment of the invention, the I signal may be represented by a cosine function having a frequency of about 1.75 GHz, while the Q signal may be represented by a sine function also having a frequency of about 1.75 GHz. The frequency mixer block 120 may mix the 1.75 GHz I signal, and the 3.5 GHz VCO signal to generate an I signal having a frequency of about 5.25 GHz. The frequency mixer block 122 may mix the 1.75 GHz Q signal, and the 3.5 GHz VCO signal to generate a Q signal having a frequency of about 5.25 GHz. The 5.25 GHz I signal may be buffered by the signal buffer 124 and output as a 5 GHz LO I signal, as referenced by the label LOI_{5G} in FIG. 1B. The 5.25 GHz Q signal may be buffered by the signal buffer 126 and output as a 5 GHz LO Q signal, as referenced by the label LOQ_{5G}.

When generating an LO signal having a frequency in the 2.5 GHz frequency band, the VCO block 106 may generate a current VCO signal having a frequency of approximately 3.2 GHz. The 3.2 GHz VCO signal may be frequency divided by the frequency divider block 118 to generate corresponding I and Q signals, each having a frequency of about 1.6 GHz. The frequency mixer block 120 may mix the 1.6 GHz I signal, and the 3.2 GHz VCO signal to generate an I signal having a frequency of about 4.8 GHz. The frequency mixer block 122 may mix the 1.6 GHz Q signal, and the 3.2 GHz VCO signal to generate a Q signal having a frequency of about 4.8 GHz. The frequency divider block 128 may frequency divide the 4.8 GHz I signal generated by the frequency mixer 120 block to generate an I signal having a frequency of about 2.4 GHz. The 2.4 GHz I signal may be buffered by the signal buffer 130 and output as referenced by the label LOI_{2.5G}. Similarly, the frequency divider block 128 may frequency divide the 4.8 GHz Q signal generated by the frequency mixer 122 block to generate a Q signal having a frequency of about 2.4 GHz. The 2.4 GHz Q signal may be buffered by the signal buffer 132 and output as referenced by the label LOQ_{2.5G}.

When generating an LO signal having a frequency in the DCS or PCS frequency band, the VCO block 106 may generate a current VCO signal having a frequency of approximately 3.8 GHz. The 3.8 GHz VCO signal may be frequency divided by the frequency divider block 134 to generate corresponding I and Q signals, each having a frequency of about 1.9 GHz. The 1.9 GHz I signal may be buffered by the signal buffer 136 and output as a 1.9 GHz LO I signal, as referenced by the label LOI_{2G} in FIG. 1B. The 1.9 GHz Q signal may be buffered by the signal buffer 138 and output as a 1.9 GHz LO Q signal, as referenced by the label LOQ_{2G}.

When generating an LO signal having a frequency in the GSM frequency band, the VCO block 106 may generate a current VCO signal having a frequency of approximately 3.6 GHz. The 3.6 GHz VCO signal may be frequency divided by the frequency divider block 134 to generate corresponding I and Q signals, each having a frequency of about 1.8 GHz. The frequency divider block 140 may frequency divide the 1.8 GHz I signal generated by the frequency divider block 134 to generate an I signal having a frequency of about 900 MHz. The 900 MHz I signal may be buffered by the signal buffer 142 and output as referenced by the label LOI_{GSM}. Similarly, the frequency divider block 140 may frequency divide the 1.8 GHz Q signal generated by the frequency divider block 134 to generate a Q signal having a frequency of about 900 MHz. The 900 MHz Q signal may be buffered by the signal buffer 144 and output as referenced by the label LOQ_{GSM}.

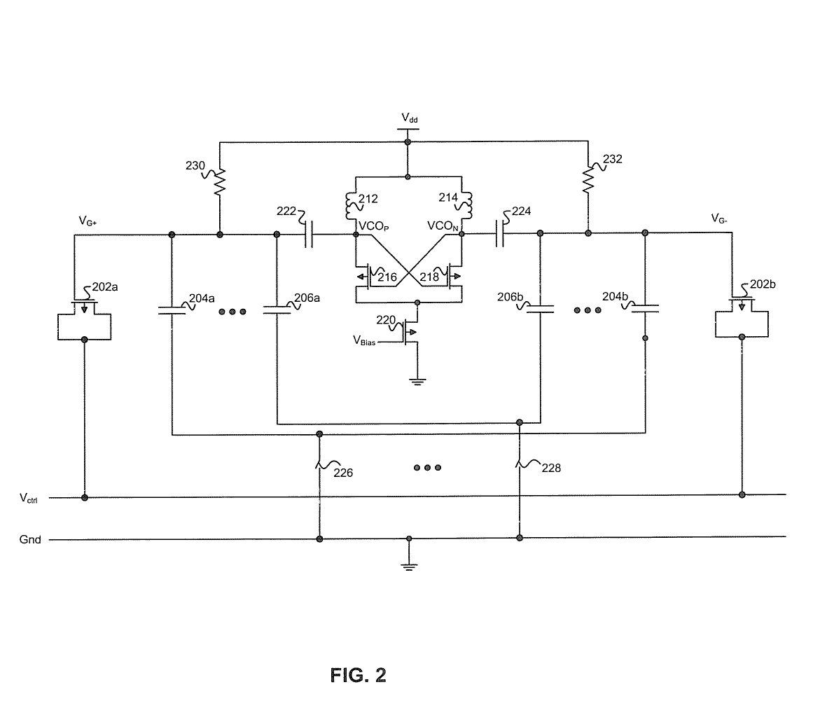

FIG. 2 is a diagram illustrating circuitry for a tunable VCO with switched capacitors, in accordance with an embodiment of the invention. Referring to FIG. 2, there is shown, varactors 202a and 202b, capacitors 222 and 224, a plurality of capacitors 204a, 204b, 206a, and 206b, inductors 212 and 214, transistors 216, 218, and 220, a plurality of switches 226 and 228, and resistors 230 and 232.

FIG. 2 presents a circuit diagram of a local oscillator circuit for which the VCO frequency, s_{VCO}, may be represented as shown in the following equation:

$${s}_{VCO} ≅ \frac{2 π}{\sqrt{{L}_{tot} \cdot {C}_{tot}}} \qquad Equation [ 8 ]$$

where Lₜₒₜ is a measure of the total inductance in the VCO circuit, and Cₜₒₜ is a measure of the total capacitance in the VCO circuit. As shown in FIG. 2, the VCO signal generated by the VCO circuit may be measured as a differential signal at the reference points labeled VCO_{P} and VCO_{N}. Energy for maintaining VCO signal oscillations at the VCO frequency may be supplied by the positive feedback circuit represented by the cross-connected transistors 216 and 218, and from the current source transistor 220. The resistors 230 and 232 may represent pull-up resistors that may be utilized to establish a voltage level for the reference points labeled V_{G+} and V_{G-} respectively.

The total inductance, Lₜₒₜ, in the VCO circuit may be represented as shown in the following equation:

Lₜₒₜ≅L₂₁₂+L₂₁₄ Equation [9]

and the total capacitance, Cₜₒₜ, in the VCO circuit may be represented as shown in the following equation:

$${C}_{tot} = \frac{{C}_{tot , P} \cdot {C}_{tot , N}}{{C}_{tot , P} + {C}_{tot , N}} \qquad Equation [ 10 ]$$

where C_{tot,P} may represent the total capacitance contributed to the VCO circuit from the varactor 202a, and capacitors 204a, 206a, and 222, and C_{tot,N} may represent the total capacitance contributed to the VCO circuit from the varactor 202b, and capacitors 204b, 206b, and 224.

The capacitance C_{tot,P} may be represented as shown in the following equation:

$${C}_{tot , P} ≅ \frac{{C}_{222} \cdot ( {C}_{202 a} + {b}_{1} \cdot {C}_{204 a} + {b}_{2} \cdot {C}_{206 a} )}{{C}_{222} + {C}_{202 a} + {b}_{1} \cdot {C}_{204 a} + {b}_{2} \cdot {C}_{206 a}} \qquad Equation [ 11 ]$$

where C₂₂₂ may represent the capacitance of the capacitor 222, C₂₀₂ₐ may represent the capacitance of the varactor 202a, C₂₀₄ₐ may represent the capacitance of the capacitor 204a, and C₂₀₆ₐ may represent the capacitance of the capacitor 206a. The variables b₁ and b₂ may represent binary selection variables for which the value is equal to 1 when the corresponding capacitor has been selected in the VCO circuit, and may be equal to 0 when the corresponding capacitor has not been selected. A capacitor may be selected based on the value of the n-bit control word utilized by the VCO control processor 108 to configure the VCO 106.

Similarly, the capacitance C_{tot,N} may be represented as shown in the following equation:

$${C}_{tot , N} ≅ \frac{{C}_{224} \cdot ( {C}_{202 b} + {b}_{1} \cdot {C}_{204 b} + {b}_{2} \cdot {C}_{206 b} )}{{C}_{224} + {C}_{202 b} + {b}_{1} \cdot {C}_{204 b} + {b}_{2} \cdot {C}_{206 b}} \qquad Equation [ 12 ]$$

where C₂₂₄ may represent the capacitance of the capacitor 224, C_{202b} may represent the capacitance of the varactor 202b, C_{204b} may represent the capacitance of the capacitor 204b, and C_{206b} may represent the capacitance of the capacitor 206b.

In various embodiments of the invention, fine tuning adjustment of the VCO frequency may be achieved by varying the capacitance of the varactors 202a, and 202b, while coarse tuning adjustment of the VCO frequency may be achieved by varying the capacitance contributed to the VCO circuit from the capacitors 204a, 204b, 206a, and 206b. The capacitance contributed to the VCO circuit by the capacitors 204a, 204b, 206a, and 206b may be determined based on the n-bit binary control word utilized by the VCO control processor 108 to configure the VCO 106. The capacitance contributed by the varactors 202a and 202b may be determined based on the control voltage, V_{cntl}.

The varactor 202a may be implemented utilizing various techniques, for example, the varactor 202a may be implemented utilizing a diode, or a transistor. In such implementations, the diode or transistor may be implemented utilizing various integrated circuit technologies, for example CMOS, or BiCMOS, and may be fabricated as an n-channel device, or a p-channel device. The capacitance of the varactor 202a may be based on the voltage level difference between the reference point in FIG. 2 labeled V_{G+}and the control voltage V_{cntl}. For decreasing values of V_{cntl}<V_{G+}, the capacitance of the varactor 202a may increase, while for increasing values of V_{cntl}<V_{G+}, the capacitance of the varactor 202a may decrease.

The varactor 202b may be substantially similar to the varactor 202a. The capacitance of the varactor 202b may be based on the voltage level difference between the reference point in FIG. 2 labeled V_{G-} and the control voltage V_{cntl}. For decreasing values of V_{cntl}<V_{G-}, the capacitance of the varactor 202b may increase, while for increasing values of V_{cntl}<V_{G-}, the capacitance of the varactor 202b may decrease.

The switch 226, when closed, may couple the capacitors 204a and 204b to ground (GND) in the VCO circuit as shown in FIG. 2. When the switch 226 is closed, the capacitors 204a and 204b may contribute to the capacitance of the VCO circuit. Referring to equations [11] and [12], closing of the switch 226 may correspond to b₁=1. By contract, when the switch 226 is opened, the capacitors 204a and 204b may not contribute to the capacitance of the VCO circuit. Referring to equations [11] and [12], opening of the switch 226 may correspond to b₁=0.

The switch 228, when closed, may couple the capacitors 206a and 206b to ground (GND) in the VCO circuit as shown in FIG. 2. When the switch 228 is closed, the capacitors 206a and 206b may contribute to the capacitance of the VCO circuit. Referring to equations [11] and [12], closing of the switch 228 may correspond to b₂=1. By contract, when the switch 228 is opened, the capacitors 206a and 206b may not contribute to the capacitance of the VCO circuit. Referring to equations [11] and [12], opening of the switch 228 may correspond to b₂=0.

In another exemplary embodiment of the invention, the switches 226 and 228 may not be limited to coupling the capacitors 204a, 204b, 206a, and 206b to GND but may couple the capacitors to, for example, a voltage source, or other node for which the voltage level may be nonzero.

In various embodiments of the invention, a bit from the n-bit control word may enable control of a corresponding switch among a plurality of switches in the VCO circuit. Thus, the control word generated by the VCO control processor 108 may enable coarse tuning adjustment of the VCO frequency by controlling the opening and closing of switches 226 and 228 in the VCO circuit. When the number of closed switches is increased in response to the control word, the capacitance of the VCO circuit may increase. As shown in equation [3], the increase in the capacitance of the VCO circuit may result in a corresponding decrease in the VCO gain factor, K_{VCO}. As a result, the VCO frequency may decrease for a given level of the control voltage, V_{cntl}.

By contrast, an increase in the control voltage V_{cntl} may result in a decrease in the capacitance of the varactors 202a and 202b. For example, for values of C₂₀₂ₐ, which are small in comparison to the total capacitance (b₁·C₂₀₄ₐ+b₂·C₂₀₆ₐ), the value of K_{VCO} may vary little in response to changes in the control voltage. Thus, the VCO frequency may be approximated as changing linearly, based on the VCO gain factor, in response to changes in the control voltage as shown in equation [2]. Based on the linear approximation, fine tuning adjustments in the VCO frequency, s_{VCO}, may be realized based on changes in the control voltage V_{cntl}, in various embodiments of the invention. The value m₁ may represent a binary value that may indicate whether the varactors 304a and 304b may be coupled to GND or to V_{dd}. For example, m₁=1 may indicate that the varactors 304a and 304b may be coupled to GND, and s₁=0 may indicate that the varactors 304a and 304b may be coupled to V_{dd}.

Similarly, b₂ may represent a binary value that may indicate whether the varactors 306a and 306b are coupled to either GND or V_{dd}. For example, b₂=1 may indicate that the varactors 306a and 306b may be coupled to either GND or V_{dd}, and b₂=0 may indicate that the varactors 306a and 306b may not contribute capacitance to the VCO circuit. The selector indicator m₂ may represent a binary value that may indicate whether the varactors 306a and 306b may be coupled to GND or to V_{dd}. For example, m₂=1 may indicate that the varactors 306a and 306b may be coupled to GND, and m₂=0 may indicate that the varactors 306a and 306b may be coupled to V_{dd}.

In various embodiments of the invention, values for the bits b₁, m₁, b₂, and m₂ may be determined based on the binary control word from the VCO control processor 108.

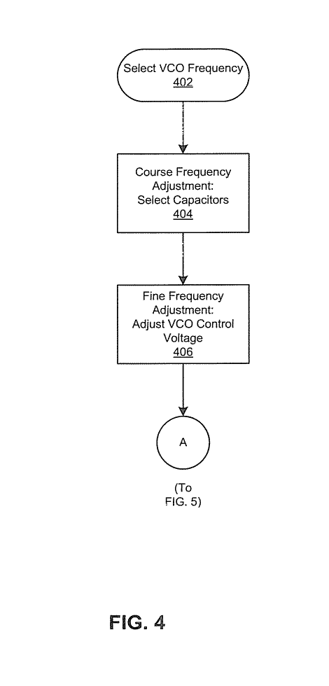

FIG. 4 is a flow chart illustrating exemplary steps for selecting a VCO frequency, in accordance with an embodiment of the invention. Referring to FIG. 4, step 402 may indicate initiation of a procedure for selecting a VCO frequency. In step 404, coarse frequency adjustment may be performed by configuring switched capacitors 204a, 204b, 206a, and 206b in the VCO circuit. The coarse frequency adjustment may be based on a control word received from the VCO control processor 108. In step 406, fine-tuning adjustment may be performed by generating a control voltage, V_{cntl}. The control voltage may be generated based on a reference signal, generated by a crystal oscillator for example, and a feedback signal, generated by the Frac N synthesizer block 112, for example. The VCO signal may be generated by the VCO 106.

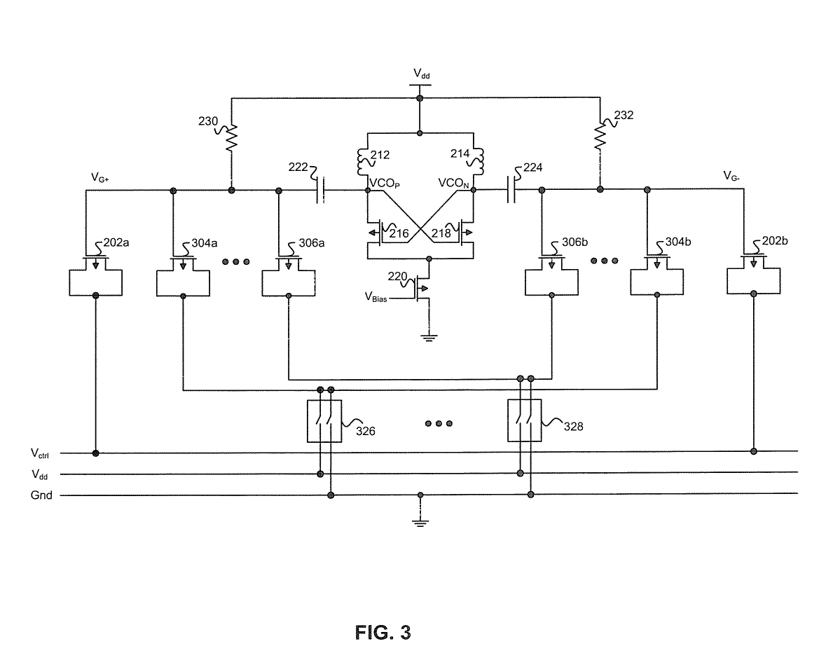

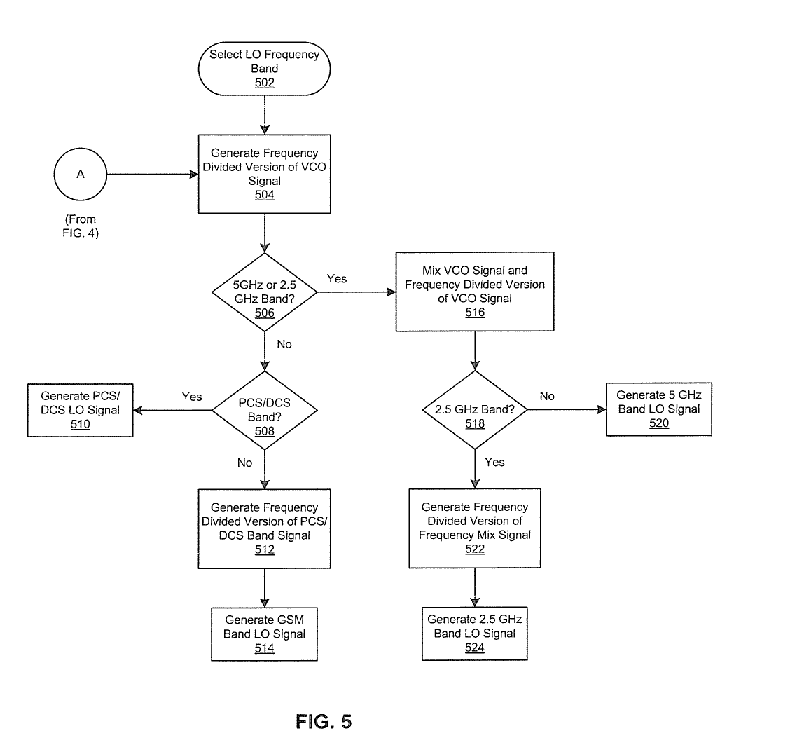

FIG. 5 is a flow chart illustrating exemplary steps for generating a LO frequency within a selected frequency band, in accordance with an embodiment of the invention. Referring to FIG. 5, step 502 may indicate the imitation of a procedure for selecting a LO frequency. In step 504 a frequency divided version of the VCO signal may be generated by the frequency divider blocks 118 and/or 134. Step 506 may [053] FIG. 3 is a diagram illustrating exemplary circuitry for a tunable VCO with switched varactors, in accordance with an embodiment of the invention. Referring to FIG. 3, there is shown, varactors 202a and 202b, capacitors 222 and 224, a plurality of varactors 304a, 304b, 306a, and 306b, inductors 212 and 214, transistors 216, 218, and 220, a plurality of switches 326 and 328, and resistors 230 and 232.

FIG. 3 differs from FIG. 2 in that the switched capacitors 204a, 204b, 206a, and 206b are replaced with switched varactors 304a, 304b, 306a, and 306b. In addition, the switches 326 and 328 may couple the varactors to a low voltage level, for example GND, or to a high voltage level, for example V_{dd}. When the switch 326 couples the varactor 304a to GND, the capacitance C₃₀₄ₐ may be equal to a capacitance C_{304High}. When the switch 326 couples the varactor 304a to V_{dd}, the capacitance C₃₀₄ₐ may be equal to a capacitance C_{304LOW}. When the switch 328 couples the varactor 306a to GND, the capacitance C₃₀₆ₐ may be equal to a capacitance C_{306High}. When the switch 328 couples the varactor 306a to V_{dd}, the capacitance C₃₀₆ₐ may be equal to a capacitance C_{306Low}.

The equations [11] and [12] may be modified as shown in the following equations:

$$\begin{matrix}{C}_{tot , P} ≅ \frac{{C}_{222} \cdot ( {C}_{202 a} + {b}_{1} \cdot ( {m}_{1} \cdot {C}_{304 High} + ( 1 - {m}_{1} ) \cdot {C}_{304 Low} ) + {b}_{2} \cdot ( {m}_{2} \cdot {C}_{306 High} + ( 1 - {m}_{2} ) \cdot {C}_{306 Low} ) )}{{C}_{222} + {C}_{202 a} + {b}_{1} \cdot ( {m}_{1} \cdot {C}_{304 High} + ( 1 - {m}_{1} ) \cdot {C}_{304 Low} ) + {b}_{2} \cdot ( {m}_{2} \cdot {C}_{306 High} + ( 1 - {m}_{2} ) \cdot {C}_{306 Low} )} \\ and & Equation [ 13 ] \\ {C}_{tot , N} ≅ \frac{{C}_{222} \cdot ( {C}_{202 b} + {b}_{1} \cdot ( {m}_{1} \cdot {C}_{304 High} + ( 1 - {m}_{1} ) \cdot {C}_{304 Low} ) + {b}_{2} \cdot ( {m}_{2} \cdot {C}_{306 High} + ( 1 - {m}_{2} ) \cdot {C}_{306 Low} ) )}{{C}_{222} + {C}_{202 b} + {b}_{1} \cdot ( {m}_{1} \cdot {C}_{304 High} + ( 1 - {m}_{1} ) \cdot {C}_{304 Low} ) + {b}_{2} \cdot ( {m}_{2} \cdot {C}_{306 High} + ( 1 - {m}_{2} ) \cdot {C}_{306 Low} )} & Equation [ 14 ]\end{matrix}$$

where b₁ may represent a binary value that may indicate whether the varactors 304a and 304b are coupled to either GND or V_{dd}. For example, b₁=1 may indicate that the varactors 304a and 304b may be coupled to either GND or V_{dd}, and b₁=0 may indicate that the varactors 304a and 304b may not contribute capacitance to the VCO circuit. determine whether the LO signal is to have a frequency in the 5 GHz band, or 2.5 GHz band. If in step 506 it is determined that the LO signal is not to have a frequency in the 5 GHz band or 2.5 GHz band, step 508 may be utilized to determine whether the LO signal is to have a frequency in the DCS and/or PCS frequency band. If in step 508 it is determined that the LO signal is to have a frequency in the DCS and/or PCS frequency band, in step 510, the DCS and/or PCS LO signals may be generated and output via the buffers 136 and 138.

If in step 508 determines that the LO signal is not to have a frequency in the PCS and/or DCS frequency band, in step 512, a frequency divided version of the DCS/PCS LO signal may be frequency divided by the frequency divider block 140. In step 514, a GSM LO frequency may be generated an output via the buffers 142 and 144.

If step 506 it is determined that the LO signal is to have a frequency in the 2.5 GHz or 5 GHz frequency bands, in step 516, the VCO signal may be frequency mixed, by the frequency mixer blocks 120 and 122, with the frequency divided version of the VCO signal from step 504. Step 518 may determine whether the LO signal is to have a frequency in the 2.5 GHz frequency band. If in step 518 it is determined that the LO signal is not to have a frequency in the 2.5 GHz band, the frequency mixed signal, generated in step 516 may be output via the buffers 124 and 126 as a 5 GHz band LO signal.

If in step 518 it is determined that the LO signal is to have a frequency in the 2.5 GHz band, in step 522, the frequency divider block 128 may generate a frequency divided version of the frequency mixed signal, generated in step 516. In step 524, a LO signal having a frequency in the 2.5 GHz band may be output via the buffers 130 and 132.

Aspects of a method and system for identifying a local oscillator (LO) generator architecture for multi-band wireless systems may comprise a VCO control processor 108 and/or Frac N control processor 114 that may enable selection, from a plurality of frequencies, of a frequency of oscillation of a signal generated by a single VCO 106 by enabling configuration of one or more capacitor and/or varactor circuits in a multi-standard wireless communication system that processes a plurality of RF signals located in different frequency bands using the single VCO 106. In response to the selection, at least one circuit may enable generation, utilizing the single VCO 106, of a local oscillator signal having a frequency within a plurality of frequency ranges comprising 850 MHz to 1 GHz, 1.7 GHz to 2.1 GHz, 2.4 GHz to 2.5 GHz, and 4.9 GHz to 5.9 GHz. The plurality of RF signals may comprise received and/or transmitted signals.

The VCO control processor 108 and/or Frac N control processor 114 may enable selection of said frequency of oscillation in the signal generated by the single VCO 106 based on a control voltage. The a VCO frequency-divided signal may be generated having a frequency that is determined by dividing the frequency of the signal generated by the single VCO 106 by a number having a value greater than 1. The local oscillator signal may have a frequency selected from the 1.7 GHz to 2.1 GHz frequency range.

The local oscillator signal may be generated having a frequency that is determined by dividing the frequency of the VCO frequency-divided signal by a number having a value greater than 1. The local oscillator signal may have a frequency selected from the 850 MHz to 1 GHz frequency range. The local oscillator signal may be generated having a frequency that is determined by frequency mixing the signal generated by the VCO 106 and the VCO frequency-divided signal. The local oscillator signal may have a frequency selected from the 4.9 GHz to 5.9 GHz frequency range. The local oscillator signal may be generated having a frequency that is determined by dividing a frequency of a signal generated by frequency mixing the signal, generated by the VCO 106 and the VCO frequency-divided signal, by a number having a value greater than 1. The local oscillator signal may have a frequency selected from the 2.4 GHz to 2.5 GHz frequency range.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for generating timing signals, the method comprising:
in a multi-standard wireless communication system that processes a plurality of RF signals located in different frequency bands using a single VCO, selecting from a plurality of frequencies, a frequency of oscillation of a signal generated by said single VCO by configuring at least one of the following: a capacitor circuit and a varactor circuit; and
in response to said selecting, generating utilizing said single VCO, a local oscillator signal having a frequency within a plurality of frequency ranges comprising 850 MHz to 1 GHz, 1.7 GHz to 2.1 GHz, 2.4 GHz to 2.5 GHz, and 4.9 GHz to 5.9 GHz.

2. The method according to claim 1, comprising selecting said frequency of said oscillation in said signal generated by said single VCO based on a control voltage.

3. The method according to claim 1, comprising generating a VCO frequency-divided signal having a frequency that is determined by dividing said frequency of said signal generated by said VCO by a number having a value greater than 1.

4. The method according to claim 3, wherein said local oscillator signal has a frequency selected from said 1.7 GHz to 2.1 GHz.

5. The method according to claim 3, comprising generating said local oscillator signal having a frequency that is determined by dividing said frequency of said VCO frequency-divided signal by a number having a value greater than 1.

6. The method according to claim 5, wherein said local oscillator signal has a frequency selected from said 850 MHz to 1 GHz.

7. The method according to claim 3, comprising generating said local oscillator signal having a frequency that is determined by frequency mixing said signal generated by said VCO and said VCO frequency-divided signal.

8. The method according to claim 7, wherein said local oscillator signal has a frequency selected from said 4.9 GHz to 5.9 GHz.

9. The method according to claim 3, comprising generating said local oscillator signal having a frequency that is determined by dividing a frequency of a signal, generated by frequency mixing said signal generated by said VCO and said VCO frequency-divided signal, by a number having a value greater than 1.

10. The method according to claim 9, wherein said local oscillator signal has a frequency selected from said 2.4 GHz to 2.5 GHz.

11. The method according to claim 1, wherein said plurality of RF signals comprises at least one of: a received signal and a transmitted signal.

12. A machine-readable storage having stored thereon, a computer program having at least one code section for generating timing signals, the at least one code section being executable by a machine for causing the machine to perform steps comprising:
in a multi-standard wireless communication system that processes a plurality of RF signals located in different frequency bands using a single VCO, selecting from a plurality of frequencies, a frequency of oscillation of a signal generated by said single VCO by configuring at least one of the following: a capacitor circuit and a varactor circuit; and
in response to said selecting, generating utilizing said single VCO, a local oscillator signal having a frequency within a plurality of frequency ranges comprising 850 MHz to 1 GHz, 1.7 GHz to 2.1 GHz, 2.4 GHz to 2.5 GHz, and 4.9 GHz to 5.9 GHz.

13. The machine-readable storage according to claim 12, wherein said at least one code section comprises code for selecting said frequency of said oscillation in said signal generated by said single VCO based on a control voltage.

14. The machine-readable storage according to claim 12, wherein said at least one code section comprises code for generating a VCO frequency-divided signal having a frequency that is determined by dividing said frequency of VCO generated by said VCO signal by a number having a value greater than 1.

15. The machine-readable storage according to claim 14, wherein said local oscillator signal has a frequency selected from said 1.7 GHz to 2.1 GHz.

16. The machine-readable storage according to claim 14, wherein said at least one code section comprises code for generating said local oscillator signal having a frequency that is determined by dividing said frequency of said VCO frequency-divided signal by a number having a value greater than 1.

17. The machine-readable storage according to claim 16, wherein said local oscillator signal has a frequency selected from said 850 MHz to 1 GHz.

18. The machine-readable storage according to claim 14, wherein said at least one code section comprises code for generating said local oscillator signal having a frequency that is determined by frequency mixing said signal generated by said VCO and said VCO frequency-divided signal.

19. The machine-readable storage according to claim 18, wherein said local oscillator signal has a frequency selected from said 4.9 GHz to 5.9 GHz.

20. The machine-readable storage according to claim 14, wherein said at least one code section comprises code for generating said local oscillator signal having a frequency that is determined by dividing a frequency of a signal, generated by frequency mixing said signal generated by said VCO and said VCO frequency-divided signal, by a number having a value greater than 1.

21. The machine-readable storage according to claim 20, wherein said local oscillator signal has a frequency selected from said 2.4 GHz to 2.5 GHz.

22. The machine-readable according to claim 12, wherein said plurality of RF signals comprises at least one of: a received signal and a transmitted signal.

23. A system for generating timing signals, the system comprising:
in a multi-standard wireless communication system that processes a plurality of RF signals located in different frequency bands using a single VCO, at least one processor that enables selection from a plurality of frequencies, of a frequency of oscillation of a signal generated by said single VCO by enabling configuration of at least one of the following: a capacitor circuit and a varactor circuit; and
in response to said selection, at least one circuit that enables generation, utilizing said single VCO, of a local oscillator signal having a frequency within a plurality of frequency ranges comprising 850 MHz to 1 GHz, 1.7 GHz to 2.1 GHz, 2.4 GHz to 2.5 GHz, and 4.9 GHz to 5.9 GHz.

24. The system according to claim 23, wherein said at least one processor enables selection of said frequency of said oscillation in said signal generated by said single VCO based on a control voltage.

25. The system according to claim 23, wherein said at least one circuit enables generation of a VCO frequency-divided signal having a frequency that is determined by dividing said frequency of said signal generated by said single VCO by a number having a value greater than 1.

26. The system according to claim 25, wherein said local oscillator signal has a frequency selected from said 1.7 GHz to 2.1 GHz.

27. The system according to claim 25, wherein said at least one circuit enables generation of said local oscillator signal having a frequency that is determined by dividing said frequency of said VCO frequency-divided signal by a number having a value greater than 1.

28. The system according to claim 27, wherein said local oscillator signal has a frequency selected from said 850 MHz to 1 GHz.

29. The system according to claim 25, wherein said at least one circuit enables generation of said local oscillator signal having a frequency that is determined by frequency mixing said signal generated by said VCO and said VCO frequency-divided signal.

30. The system according to claim 29, wherein said local oscillator signal has a frequency selected from said 4.9 GHz to 5.9 GHz.

31. The system according to claim 25, wherein said at least one circuit enables generation of said local oscillator signal having a frequency that is determined by dividing a frequency of a signal, generated by frequency mixing said signal generated by said VCO and said VCO frequency-divided signal, by a number having a value greater than 1.

32. The system according to claim 31, wherein said local oscillator signal has a frequency selected from said 2.4 GHz to 2.5 GHz.

33. The system according to claim 23, wherein said plurality of RF signals comprises at least one of: a received signal and a transmitted signal.
